(19) United States
(12) Patent Application Publication
(10) Pub. No.: US 2012/0090539 A1
(43) Pub. Date: Apr. 19, 2012

(54) LIQUID INFUSION DEVICE AND METHOD

(75) Inventors: Justin James Dutton, San Diego, CA (US); Paul Christopher Ziegelbauer, San Diego, CA (US); Doron Greenberg, Agoura Hills, CA (US); David James Brecht, San Diego, CA (US); Bin Li, San Diego, CA (US)

(73) Assignee: Wildcat Discovery Technologies, San Diego, CA (US)

(21) Appl. No.: 13/272,469

(22) Filed: Oct. 13, 2011

Related U.S. Application Data
(60) Provisional application No. 61/393,451, filed on Oct. 15, 2010.

(51) Int. Cl. C23C 14/00

(52) U.S. Cl. 118/50; 427/294

(57) ABSTRACT

A device for infusing liquid into material samples includes a container assembly configured to contain multiple material samples submerged in liquid. The material samples have pores containing air or gas. A pressure source and a vacuum source are both operatively connectable to the container assembly and alternately communicable with the container assembly to force the liquid to at least substantially fill the pores. The samples are thus ready for further processing, testing or use. A method of filling pores in material samples with liquid includes supporting multiple material samples within liquid in an airtight container assembly. The method further includes alternately applying a vacuum source and a pressure source to the container assembly, thereby replacing air with liquid in the pores of the material samples.

### CROSS-REFERENCE TO RELATED APPLICATIONS

This application claims the benefit of United States Provisional Application No. 61/393,451 filed Oct. 15, 2010, which is hereby incorporated by reference in its entirety.

### TECHNICAL FIELD

The invention relates to a device for infusing liquid into pores of material samples, and a method for the same.

### BACKGROUND

Some materials are initially formed with pores. The pores may be permeated by surrounding air, thereby becoming air pockets. In certain applications, a gas other than air may fill the pores. In some instances, the pores must be filled with liquid in order for the material to be used for a desired purpose. For example, a number of anode and cathode materials used in batteries are initially formed with air pockets. The air pockets must be filled with electrolyte in order for the material to function efficiently within a battery. Existing processes for filling air pockets in this manner are time consuming, and are generally limited to processing only one material sample at a time. For example, electrolyte may be placed in a syringe with the material sample. The atmosphere in the syringe is placed under vacuum by manually pulling on the syringe plunger to remove air entrapped within the pellet. The atmosphere in the syringe is then placed under pressure by pushing on the syringe plunger to force the electrolyte into the now open air pockets (i.e., free of air that would otherwise provide resistance to the liquid entering the air pockets). The pressurizing and vacuuming process is repeated a number of times until it is determined that the pellet of material is sufficiently soaked in the liquid (i.e., the pores are sufficiently full of liquid). The pellets may sink in the liquid within the syringe when sufficiently soaked, which may serve to indicate that the soaking process is complete. Another existing method involves the use of a re-sealable plastic storage bag, such as a ZIPLOC® bag in which material samples and liquid are contained. ZIPLOC® is a registered trademark of S.C. Johnson & Son, Inc., 1525 Howe Street Racine Wis. 53403. By squeezing the ZIPLOC® bag, pressure within the bag is increased and some liquid may be forced into the pores of the material sample. This method is limited to applying pressure only (no vacuum). The pressure range is also limited to the strength of the seal on the ZIPLOC® bag.

The current syringe soaking process described above has several disadvantages. The existing procedure requires significant time, averaging 10-15 minutes per single pellet to manually operate the syringe to remove air from the pellet pockets and replace the air with electrolyte. The current procedure is also known to yield inconsistent results. Depending on the syringe used and the strength of the user, both the level of vacuum and the pressure level generated within the syringe can vary significantly. This can lead to inconsistent and/or subpar battery performance (in terms of capacity, charging rates, cycle life, etc). The existing syringe procedure also limits pellet size, as appropriate syringes may not be available for relatively large pellet sizes. Changes in the syringe size also have adverse effects on internal pressures achievable; as the diameter of the syringe goes up, the internal pressure range becomes less extreme, decreasing the effectiveness of air removal. Sizes of commercially-available syringes are also limiting.

### SUMMARY

A device for infusing liquid into pores of material samples includes a container assembly configured to contain multiple material samples submerged in liquid. A vacuum source is selectively operatively connectable to the container assembly and is operable to apply a vacuum to the liquid. A pressure source is selectively operatively connectable to the container assembly and is operable to apply pressurized gas to the liquid. The vacuum source and the pressure source are configured to be alternately communicable with the container assembly to force air or gas from the pores and force the liquid to at least substantially fill the pores. The samples are thus soaked in the liquid and prepared for further testing or use. The device is especially useful for preparing anode and cathode material samples by forcing electrolyte into pores of the material samples.

A method of infusing liquid into pores of material samples includes supporting multiple material samples within liquid in an at least substantially airtight container assembly. The method further includes alternately applying a vacuum source and a pressure source to the container assembly, thereby replacing air with liquid in the pores of the material samples.

The pressure source and the vacuum source provide consistent pressure and vacuum levels so that the material samples are more consistently filled with liquid than with previous material soaking apparatuses and methods. Furthermore, the container assembly is configured to support multiple material samples so that the method may be accomplished at a relatively high throughput rate. The size of the container assembly may be selected to allow a relatively large number of material samples to be processed simultaneously. Because the vacuum source and pressure source can be controlled at consistent vacuum and pressure levels, respectively, the method permits more efficient and consistent processing of the material samples.

The above features and advantages and other features and advantages of the present invention are readily apparent from the following detailed description of the best modes for carrying out the invention when taken in connection with the accompanying drawings.

### BRIEF DESCRIPTION OF THE DRAWINGS

FIG. 1 is a schematic side view illustration of a liquid infusion device;

FIG. 2 is a schematic fragmentary cross-sectional illustration of a portion of the liquid infusion device of FIG. 1 showing material samples within the device;

FIG. 3 is a schematic side view illustration of one of the material samples of FIG. 2; and

FIG. 4 is a flow diagram of a method of infusing liquid into material samples.

### DETAILED DESCRIPTION

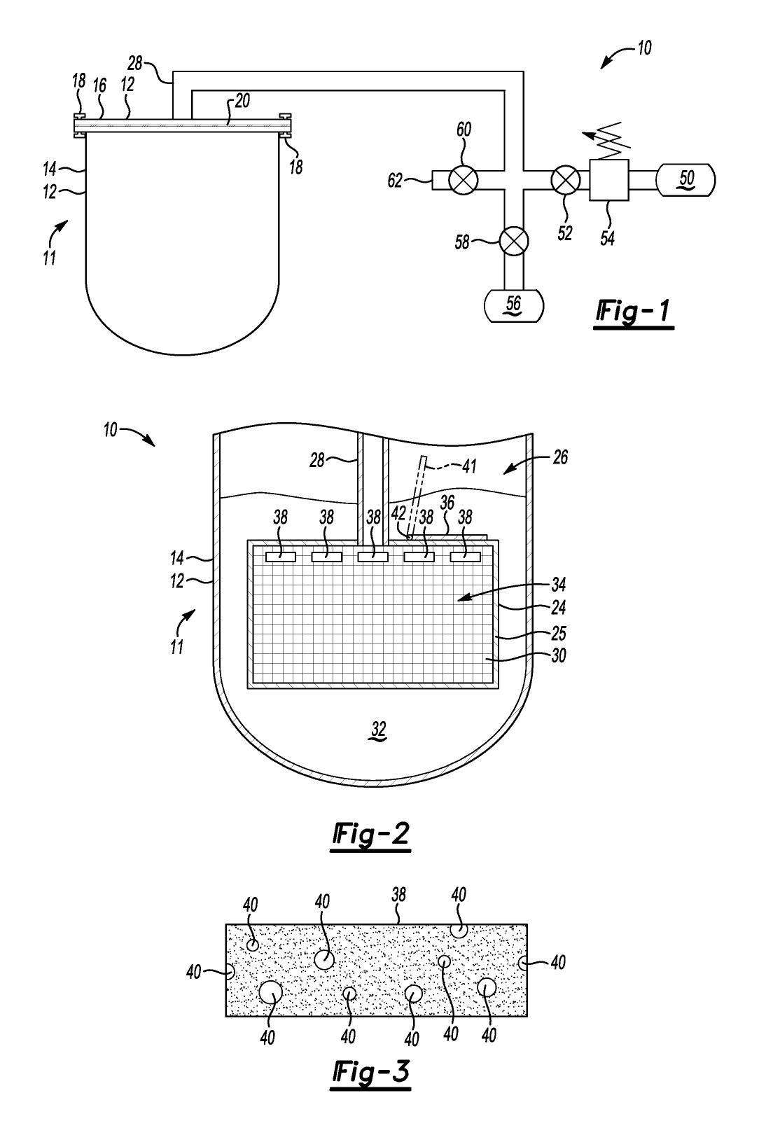

Referring to the drawings, wherein like reference numbers refer to like components throughout the several views, FIG. 1 shows a liquid infusion device 10 configured to consistently and efficiently infuse liquid into multiple material samples on a high-throughput basis. The liquid infusion device 10 includes a container assembly 11 with an outer container 12, also referred to herein as a first container. The outer container 12 includes a well portion 14 and a lid 16. The lid 16 is secured to the well portion 14 by at least one fastener 18 with a seal 20 to close the outer container 12 so that it is at least substantially and preferably completely airtight and leak-free under a predetermined pressure range. In another embodiment, the lid 16 has external threads and the well portion 14 has internal threads so that the lid 16 can be screwed onto the well portion 14. In the embodiment shown, the lid 16 is removable by removing the fasteners 18 in order to open the container 12 to place material samples 38, shown in FIG. 2, within the well portion 14, as further discussed below.

Referring to FIG. 2, the well portion 14 of the outer container 12 is shown in partial cross-sectional view to reveal an inner container 24 of the container assembly 11. The inner container 24 is also referred to as a second container. The inner container 24 is suspended within an interior cavity 26 defined by the outer container 12. The inner container 24 may be connected to and suspended by gas flow tubing 28 into liquid 32 that at least partially fills the cavity 26, or may be otherwise mounted within the interior cavity 26 of the outer container 12.

The inner container 24 has a basket portion 25 that is a wire mesh material that defines apertures 30. The apertures 30 permit the liquid 32 that at least partially fills the cavity 26 to also enter an interior space 34 defined by the inner container 24. The inner container 24 may have a wire mesh lid 36 that is hinged to the basket portion 25 and that is openable and closable to permit material samples 38 to be placed within the interior space 34. The wire mesh lid 36 is shown in an open position 41, pivoted about hinge 42. In other embodiments, it may be desirable for the entire lid of the inner container 24 to be removable. The apertures 30 are smaller than the material samples 38 placed in the basket portion 25, so that the material samples are retained within the basket portion 25.

As an alternative to wire mesh, the inner container 24 may be any material and construction that has apertures that are sized to permit liquid 32 to enter the inner container 24 but that are small enough to prevent material samples 38 from exiting the inner container 24. The material samples 38 may all be of the same material, or may be different materials processed simultaneously.

Referring to FIG. 3, a representative material sample 38 is shown. The material sample 38 is compressed as a pellet. Even though compressed, the material sample 38 still defines pores 40 that may be referred to as recesses or air pockets. The size of the pores 40 is exaggerated for purposes of illustration in FIG. 3. In one representative example, the material samples 38 may be anode or cathode material for use in a battery, and the liquid 32 may be electrolyte. Anode and cathode materials provide a better performance in a battery if electrolyte fills any pores 40 remaining after compression of the samples 38. The liquid infusion device 10 may be used for infusing a wide array of material samples 38 with a wide variety of liquids 32 for which it is determined to be desirable to fill the pores 40 with liquid 32 by driving air or other gas out of the pores 40. As shown in FIG. 2, the material samples 38 may float to the top of the basket 25 before the method 100 described below is completed (i.e., before the pores 40 are filled with liquid 32).

The liquid infusion device 10 is configured to fill the pores 40 of FIG. 3 in the material samples 38 with liquid 32 in a consistent and efficient manner. Referring again to FIG. 1, the liquid infusion device 10 includes tubing, valves, and pressure and vacuum sources that provide the desired infusing operation. Specifically, a gas pressure source 50 containing pressurized gas, such as air, is in selective fluid communication with the material samples 38 through tubing 28, by opening a pressure shutoff valve 52. Pressurized gas is provided to the container assembly 11 through the tubing 28 from the pressure source 50 when the pressure shutoff valve 52 is open. A pressure regulator valve 54 is positioned downstream of the pressure source 50 and upstream of the pressure shutoff valve 52 so that the pressurized gas may be controlled to a predetermined pressure or pressure range. For example, the controlled gas pressure range could be between 0 and 150 pounds per square inch (psi). The pressurized gas pushes the liquid 32 to force it into the pores 40 of FIG. 3.

Furthermore, a vacuum source 56, such as a vacuum pump, is in selective fluid communication with the material samples 38 through the tubing 28, by opening a vacuum shutoff valve 58. When the vacuum shutoff valve 58 is open, a vacuum is applied to the container assembly 11, which tends to remove the air or gas from the pores 40 of FIG. 3. By alternating the opening and closing of the pressure shutoff valve 52 with the opening and closing of the vacuum shutoff valve 58, gas or air is repeatedly drawn from the pores 40 by the vacuum source 56, with liquid 32 being forced by the pressure source 50 to fill the pores 40 in place of the withdrawn air or gas.

The liquid infusion device 10 also includes a pressure relief valve 60. When the pressure relief valve 60 is open, the tubing 28 is in fluid communication with the surrounding atmosphere at an open end 62 of the tubing 28. Any pressure or vacuum within the tubing 28 and the interior cavity 26 will be relieved. The pressure relief valve 60 is opened when cycling of the vacuuming and pressurizing is complete, prior to removing the material samples 38 from the container assembly 11. The samples may then be removed by opening the lid 16 of the outer container 12, and then opening the lid 40 of the inner container 24.

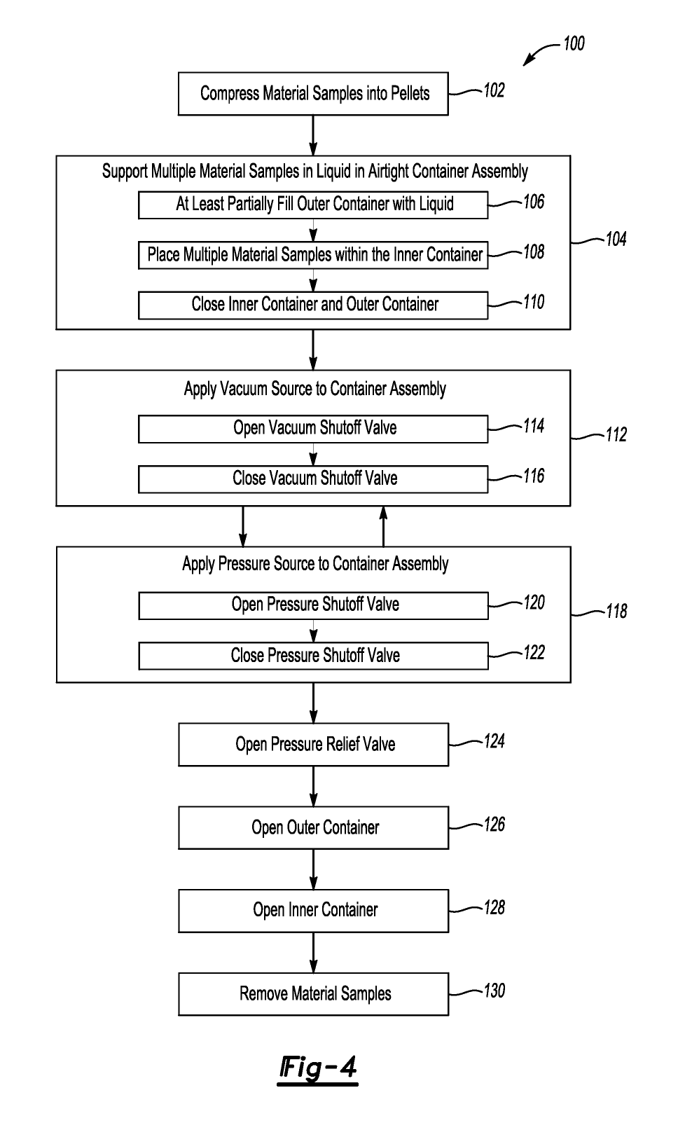

Referring to FIG. 4, a method 100 of infusing material samples with liquid is described with respect to the liquid infusion device 10 of FIGS. 1 and 2 and the material samples 38 of FIGS. 2 and 3. The method 100 begins with optional block 102, in which material samples 38 are compressed into pellets. Alternately, the material samples 38 may be provided in a pre-compressed state, or may not be compressed, depending on the expected use of the material samples 38 and the composition of the material samples 38.

In block 104, the material samples 38 are supported in liquid 32 in an airtight container assembly 11. Block 104 includes blocks 106, 108 and 110. In block 106, an outer container 12 of the container assembly 11 is at least partially filled with liquid 32. In block 108, multiple material samples 38 are then placed within the inner container 24 of the container assembly 11. In block 110, the inner container 24 and the outer container 12 are then closed by closing the lids 36 and 16, respectively.

The material samples 38 are now ready for processing in blocks 112 and 118. Specifically, in block 112 a vacuum source 56 is applied to the container assembly 11. Block 112 may include block 114, in which a vacuum shutoff valve 58 is opened to establish fluid communication between the container assembly 11 and the vacuum source 56. Block 112 may also include block 116, in which the vacuum shutoff valve 58 is then closed so that the vacuum source 56 is no longer in communication with the container assembly 11.

In block 118, a pressure source 50 is then applied to the container assembly 11. Alternately, the block 118 may initially be carried out prior to block 112 before alternating between the blocks 112, 118. Block 118 may include block 120, in which a pressure shutoff valve 52 is opened. Block 118 may also include block 122, in which the pressure shutoff valve 52 is then closed. The method 100 may cycle back and forth between blocks 112 and 118 a number of times until it is expected that the material samples 38 are in a desired condition for use or further testing, specifically with the pores 40 completely or substantially filled with liquid 32. This may be indicated by the material samples 38 tending to sink in the liquid 32 in the inner container 24.

After cycling through blocks 112 and 118, a pressure relief valve 60 is opened in block 124 to bring the pressure of the container assembly 11 and tubing 28 to that of the surrounding atmosphere. The outer container 12 is then opened in block 126. The inner container 24 can then be opened in block 128. The material samples 38 are then removed in block 130. The container assembly 11 can then be reused for processing additional like material samples 38, or material samples of a different material either with the same liquid 32 or with a different liquid if liquid 32 is removed from the container assembly 11.

The container assembly 11 and method 100 provide high-throughput liquid infusion of material samples 38, filling pores 40 with liquid 32. The regulated pressure from pressure source 50 and the vacuum of vacuum source 56 provide consistent processing of the material samples 38 to ensure that the pores 40 are filled completely or to a desired amount. Furthermore, the liquid infusion is accomplished for multiple material samples 38 simultaneously. The size of the container assembly 11 may be selected so that a very large number of material samples 38 may be simultaneously processed on a high-throughput basis.

While the best modes for carrying out the invention have been described in detail, those familiar with the art to which this invention relates will recognize various alternative designs and embodiments for practicing the invention within the scope of the appended claims.

1. A device for infusing liquid into pores of material samples comprising:
a container assembly configured to contain multiple material samples submerged in liquid;
a vacuum source selectively operatively connectable to the container assembly and operable to apply a vacuum to the liquid;
a pressure source selectively operatively connectable to the container assembly and operable to apply pressurized gas to the liquid; and
wherein the vacuum source and the pressure source are configured to be alternately operatively connected to the container assembly to force air or gas from the pores and force the liquid to at least substantially fill the pores.

2. The device of claim 1, wherein the container assembly includes:
an outer container configured to be openable and closable and to be substantially airtight when closed;
an inner container configured to be suspended within the outer container; wherein the inner container has apertures that admit liquid from the outer container; and wherein the apertures are sized so that the inner container retains the material samples.

3. The device of claim 2, wherein the inner container is a wire mesh container with a wire mesh lid.

4. The device of claim 1, further comprising:
a pressure regulator valve operatively connected to the pressure source and selectively operatively connectable to the container assembly downstream of the pressure source and upstream of the container assembly in a flow of the pressurized gas and configured to control the flow of the pressurized gas from the pressure source at a predetermined pressure or pressure range;
a pressure shutoff valve downstream of the pressure regulator valve and upstream of the container assembly; wherein the pressure shutoff valve is openable to permit the flow of the pressurized gas at the predetermined pressure or pressure range to the container assembly.

5. The device of claim 1, wherein the vacuum source is a vacuum pump, and further comprising:
a vacuum shutoff valve openable to operatively connect the vacuum source to the container assembly and closable to prevent fluid communication between the vacuum source and the container assembly.

6. The device of claim 1, further comprising:
a pressure relief valve operatively connected to the container assembly and configured to be selectively openable to establish fluid communication between the container assembly and a surrounding atmosphere, thereby relieving the vacuum or the pressurized gas.

7. The device of claim 1, in combination with the material samples and the liquid; wherein the material samples are one of anode and cathode materials; and
wherein the liquid is electrolyte.

8. A method of filling pores in material samples with a liquid, comprising:
supporting multiple material samples within liquid in an at least substantially airtight container assembly;
alternately applying a vacuum source and a pressure source to the container assembly, thereby replacing air or gas in the pores with the liquid.

9. The method of claim 8, wherein the container assembly includes an outer container and an inner container; wherein the inner container has apertures smaller than the material samples and is suspended within the outer container; and wherein the supporting includes:
opening the outer container;
at least partially filling the outer container with liquid; and
placing the multiple material samples within the inner container.

10. The method of claim 8, wherein the applying a vacuum source includes:
opening a vacuum shutoff valve to establish fluid communication between the vacuum source and the container assembly.

11. The method of claim 8, wherein the applying a pressure source includes:
opening a pressure shutoff valve to admit pressurized gas from the pressure source into the container assembly; wherein the pressurized gas is controlled at a predetermined pressure or pressure range by a pressure regulator valve.

12. The method of claim 8, further comprising:
opening a pressure relief valve operatively connected to the container assembly to establish fluid communication between the container assembly and a surrounding atmosphere.

13. A device for infusing liquid into pores of material samples comprising:
a first openable and closeable container defining an interior cavity and configured to hold liquid within the interior cavity and to be substantially airtight when closed;
a second container within the interior cavity configured with apertures that are sized to retain material samples within the second container and that admit liquid from the first container into the second container;
a first valve and a second valve each of which is selectively openable and closeable;
a vacuum source operatively connected to the interior cavity when the first valve is opened;
a pressure source operatively connected to the interior cavity when the second valve is opened; and
wherein the first and second valves are alternately openable and closable to apply a vacuum and to pressurize the interior cavity, respectively, to thereby replace air or gas in the pores of the material samples with the liquid.
